(19) United States
(12) Patent Application Publication
(10) Pub. No.: US 2026/0031171 A1
(43) Pub. Date: Jan. 29, 2026

(54) ARCHITECTURE FOR DETERMINISTIC MEMORY INITIALIZATION FOR AUTOMOTIVE ELECTRONICS

(71) Applicant: QUALCOMM Incorporated, San Diego, CA (US)

(72) Inventors: Swetashree MISHRA, Bengaluru (IN); Ankit SHAMBHU, Bangalore (IN); Sateeshkumar INJARAPU, Bangalore (IN); Amit DUGGAL, Bangalore (IN); Nitin JAISWAL, Bangalore (IN)

(21) Appl. No.: 18/784,704

(22) Filed: Jul. 25, 2024

(51) Int. Cl. G11C 29/36; G01R 31/317

(52) U.S. Cl. CPC G11C 29/36; G01R 31/31724

(57) ABSTRACT

Aspects of the disclosure are directed to deterministic memory initialization. In accordance with one aspect, the disclosure includes initializing a first current memory address in a plurality of memories to a first memory address using a plurality of shared built-in self-test (BIST) resources; writing a first deterministic pattern to a first memory data word specified by the first current memory address using the plurality of shared BIST resources; and incrementing the first current memory address to a first subsequent memory address using the plurality of shared BIST resources.

### TECHNICAL FIELD

This disclosure relates generally to the field of automotive electronics, and, in particular, to deterministic memory initialization in automotive computing systems.

### BACKGROUND

An information processing system, for example, an automotive computer, strives for high performance in a constrained physical environment. One requirement is a deterministic initialization of memory. One solution requires additional counter-based hardware for this initialization. However, since automotive electronic systems are constrained in area and physical resources, an architecture for deterministic memory initialization is needed.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

In one aspect, the disclosure provides for deterministic memory initialization. Accordingly, disclosed herein is an apparatus including: a memory configured to store a memory data word; and a memory built-in self-test (MBIST) module coupled to the memory, the MBIST module configured to implement diagnostic check of the memory and to initialize the memory with a deterministic pattern. In one example, the apparatus further includes a processor coupled to the memory; and a logical built-in self-test (LBIST) module coupled to the processor, the LBIST module configured to validate logic functionality of the processor.

In one example, the MBIST module is further configured to write the deterministic pattern to the memory data word specified by a current memory address using a plurality of shared built-in self-test (BIST) resources. In one example, the deterministic pattern is a pseudorandom sequence generated by a finite state machine. In one example, the memory data word includes an associated parity word. In one example, the MBIST module is further configured to increment the current memory address to a subsequent memory address using the plurality of shared BIST resources.

Another aspect of the disclosure provides an apparatus for implementing deterministic memory initialization, the apparatus including: means for initializing a current memory address in a plurality of memories to a memory address using a plurality of shared built-in self-test (BIST) resources in a computing system; means for writing a deterministic pattern to a memory data word specified by the current memory address using the plurality of shared BIST resources; means for incrementing the current memory address to a subsequent memory address using the plurality of shared BIST resources; and means for determining if the current memory address equals a maximum memory address.

In one example, the apparatus further includes means for executing a built-in self-test (BIST) process on a plurality of processors and a plurality of memories in the computing system during built-in self-test (BIST) mode; and means for enabling the BIST mode in the computing system.

Another aspect of the disclosure provides a method including: initializing a first current memory address in a plurality of memories to a first memory address using a plurality of shared built-in self-test (BIST) resources; writing a first deterministic pattern to a first memory data word specified by the first current memory address using the plurality of shared BIST resources; and incrementing the first current memory address to a first subsequent memory address using the plurality of shared BIST resources.

In one example, the first deterministic pattern is all zeros. In one example, the first deterministic pattern is a pseudorandom sequence generated by a finite state machine. In one example, a size of the first deterministic pattern is congruent to a size of the first memory data word. In one example, the first memory data word includes an associated parity word.

In one example, the method further includes determining if the first current memory address equals a maximum memory address. In one example, the method further includes writing a second deterministic pattern to a second memory data word specified by the first subsequent memory address using the plurality of shared BIST resources; incrementing the first subsequent memory address to a second subsequent address using the plurality of shared BIST resources; and determining if the second subsequent memory address equals the maximum memory address.

In one example, the method further includes executing a built-in self-test (BIST) process on a plurality of processors and a plurality of memories in a computing system during built-in self-test (BIST) mode. In one example, the method further includes selecting the first deterministic pattern to initialize the first memory data word to a known value.

In one example, the first subsequent memory address is equal to the first current memory address plus a programmable positive offset value. In one example, the first subsequent memory address is equal to the first current memory address minus a programmable negative offset value. In one example, the method further includes enabling the BIST mode in the computing system, wherein the first current memory address is initialized in the plurality of memories to the first memory address using the plurality of shared BIST resources in the computing system.

These and other aspects of the present disclosure will become more fully understood upon a review of the detailed description, which follows. Other aspects, features, and implementations of the present disclosure will become apparent to those of ordinary skill in the art, upon reviewing the following description of specific, exemplary implementations of the present invention in conjunction with the accompanying figures. While features of the present invention may be discussed relative to certain implementations and figures below, all implementations of the present invention can include one or more of the advantageous features discussed herein. In other words, while one or more implementations may be discussed as having certain advantageous features, one or more of such features may also be used in accordance with the various implementations of the invention discussed herein. In similar fashion, while exemplary implementations may be discussed below as device, system, or method implementations it should be understood that such exemplary implementations can be implemented in various devices, systems, and methods.

### BRIEF DESCRIPTION OF THE DRAWINGS

FIG. 1 illustrates an example information processing system.

FIG. 2 illustrates an example mode sequence for a counter-based hardware implementation for automotive computing system initialization.

FIG. 3 illustrates an example block diagram of a counter-based hardware implementation for automotive computing system initialization.

FIG. 4 illustrates an example System on a Chip (SOC) implementation with memory built-in self-test (MBIST) capability.

FIG. 5 illustrates an example mode sequence for an intrinsic hardware implementation for automotive computing system initialization.

FIG. 6 illustrates an example hardware architecture and algorithm flow for intrinsic memory initialization.

FIG. 7 illustrates an example flow diagram for deterministic memory initialization.

FIG. 8 illustrates an example intrinsic hardware implementation for automotive computing system initialization.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known structures and components are shown in block diagram form in order to avoid obscuring such concepts.

While for purposes of simplicity of explanation, the methodologies are shown and described as a series of acts, it is to be understood and appreciated that the methodologies are not limited by the order of acts, as some acts may, in accordance with one or more aspects, occur in different orders and/or concurrently with other acts from that shown and described herein. For example, those skilled in the art will understand and appreciate that a methodology could alternatively be represented as a series of interrelated states or events, such as in a state diagram. Moreover, not all illustrated acts may be required to implement a methodology in accordance with one or more aspects.

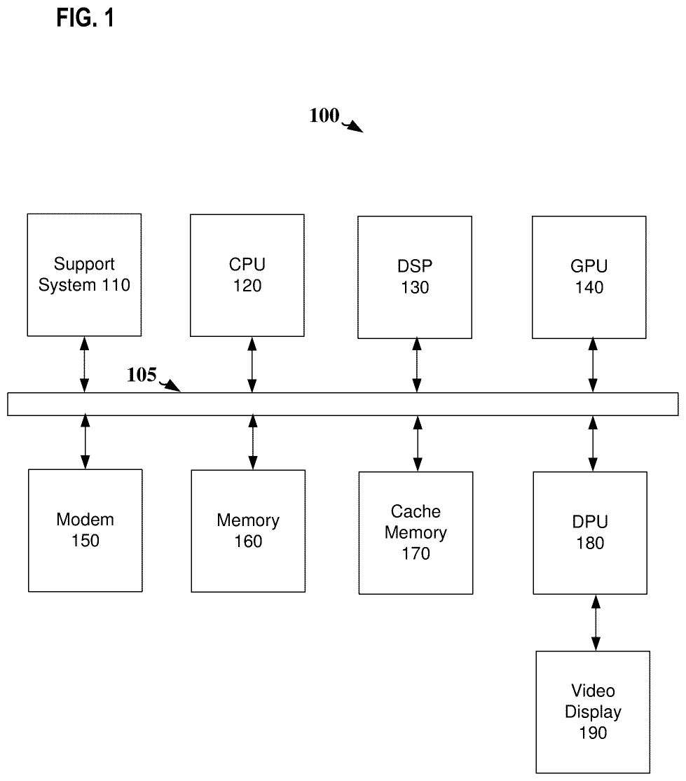

FIG. 1 illustrates an example information processing system 100. In one example, the information processing system 100 includes a plurality of processing engines, or processor cores, such as a central processing unit (CPU) 120, a digital signal processor (DSP) 130, a graphics processing unit (GPU) 140, a display processing unit (DPU) 180, etc. In one example, various other functions in the information processing system 100 may be included such as a support system 110, a modem 150, a memory 160, a cache memory 170 and a video display 190. For example, the plurality of processing engines and various other functions may be interconnected by an interconnection databus 105 to transport data and control information. For example, the memory 160 and/or the cache memory 170 may be shared among the CPU 120, the GPU 140 and the other processing engines. In one example, the CPU 120 may include a first internal memory which is not shared with the other processing engines. In one example, the GPU 140 may include a second internal memory which is not shared with the other processing engines. In one example, any processing engine of the plurality of processing engines may have an internal memory (i.e., a dedicated memory) which is not shared with the other processing engines.

Upon initialization (e.g., power up) of an automotive computing system, a plurality of memories should be initialized into a known or deterministic state. A deterministic state is required to prevent corruption (e.g., false error) of subsequent logical operations with unknown initial memory data. In general, a memory may incorporate overhead information, such as error correction coding (ECC) bits, to mitigate data corruption or soft errors in the automotive computing system. In one example, each memory word includes a data portion (i.e., with data bits) and an ECC portion (i.e., with ECC bits). In one example, ECC bits are overhead bits which are mathematically computed as a function of data bits. For example, if the data bits are subsequently corrupted, then the corruption may be detected and/or corrected using the ECC bits. If the memory includes unknown or random data during boot up (i.e., initialization), spurious ECC errors may be generated upon initialization. As a result, the plurality of memories in the automotive computing system, especially memories with ECC capability, may be initialized into a deterministic state prior to commencing an operational mode.

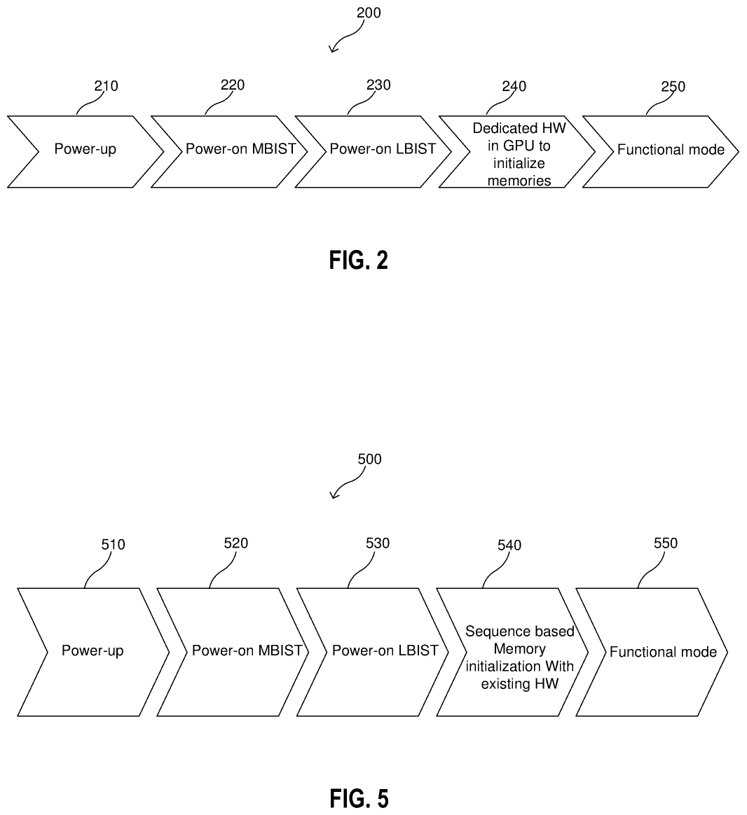

FIG. 2 illustrates an example mode sequence 200 for a counter-based hardware implementation for automotive computing system initialization. In block 210, the automotive computing system enters a power-up (i.e., initialization) mode. Next, in block 220, the automotive computing system enters a power-on memory built-in self-test (MBIST) mode. In one example, the power-on MBIST mode executes a sequence of diagnostic operations to validate proper memory functionality. Next, in block 230, the automotive computing system enters a power-on logical built-in self-test (LBIST) mode. In one example, the power-on LBIST mode executes a sequence of diagnostic operations to validate proper logic functionality. Next, in block 240, the automotive computing system enables dedicated hardware in a processing core (e.g., graphical processing unit (GPU)) to initialize memory. In one example, the dedicated hardware in a processing core may be based on a hardware counter architecture and adds additional resource overhead to the automotive computing system. Finally, in block 250, the automotive computing system transitions to a functional (e.g., operational) mode for execution of a plurality of applications.

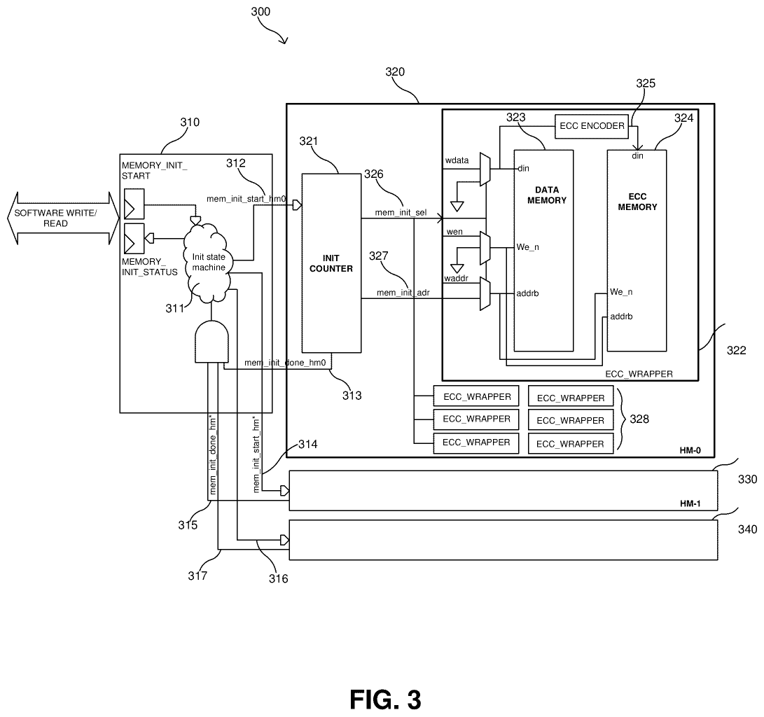

FIG. 3 illustrates an example block diagram 300 of a counter-based hardware implementation for automotive computing system initialization. In one example, a memory interface module 310 includes an initialization state machine 311 which sends a first memory initialization start signal 312 to a first hardware module (HM) 320 and receives a first memory initialization complete signal 313 from the first HM 320. In one example, the initialization state machine 311 also sends a second memory initialization start signal 314 to a second HM 330 and receives a second memory initialization complete signal 315 from the second HM 330. In one example, the initialization state machine 311 also sends a third memory initialization start signal 316 to a third HM 340 and receives a third memory initialization complete signal 317 from the third HM 340.

In one example, the first HM 320 includes an initialization counter 321 to enable initialization of a first memory module 322 (e.g., ECC_WRAPPER) using a first memory initialization select signal 326 and a first memory initialization address signal 327. In one example, the first memory module 322 includes a data memory 323 for storage of application data, an ECC memory 324 for storage of overhead ECC data and an ECC encoder 325 for computation of error correction code words as part of the overhead ECC data. In one example, the first HM 320 also includes a plurality of other memory modules 328 with similar structure to the first memory module 322.

In one example, the second HM 330 and the third HM 340 operate similarly to the first HM 320. In one example, the first HM 320, the second HM 330 and the third HM 340 require a dedicated hardware component, namely the initialization counter 321 for the first HM 320, to initialize all memories. In one example, the initialization counter 321 is not aware of power distribution network (PDN) status.

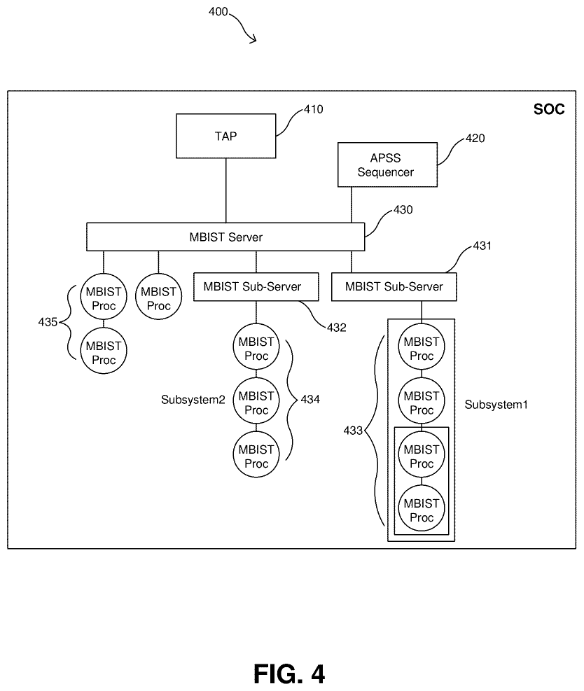

FIG. 4 illustrates an example System on a Chip (SOC) implementation with memory built-in self-test (MBIST) capability 400. The example SOC implementation includes a test access point (TAP) 410 and an application processor subsystem (APSS) 420 which both access a MBIST server 430. In one example, the MBIST server 430 includes a first MBIST sub-server 431 with a first plurality of MBIST processors 433 and a second MBIST sub-server 432 with a second plurality of MBIST processors 434 as well as a third plurality of MBIST processors 435. In one example the example SOC implementation includes MBIST functionality at a number of intellectual property (IP) levels (i.e., custom firmware levels).

FIG. 5 illustrates an example mode sequence 500 for an intrinsic hardware implementation for automotive computing system initialization. In block 510, the automotive computing system enters a power-up (i.e., initialization) mode. Next, in block 520, the automotive computing system enters a power-on memory built-in self-test (MBIST) mode. In one example, the power-on MBIST mode executes a sequence of diagnostic operations to validate proper memory functionality. Next, in block 530, the automotive computing system enters a power-on logical built-in self-test (LBIST) mode. In one example, the power-on LBIST mode executes a sequence of diagnostic operations to validate proper logic functionality. Next, in block 540, the automotive computing system enables intrinsic hardware in a processing core (e.g., graphical processing unit (GPU)) to initialize memory. In one example, the intrinsic hardware in a processing core may be based on an existing MBIST hardware with additional software to the automotive computing system. Finally, in block 550, the automotive computing system transitions to a functional (e.g., operational) mode for execution of a plurality of applications.

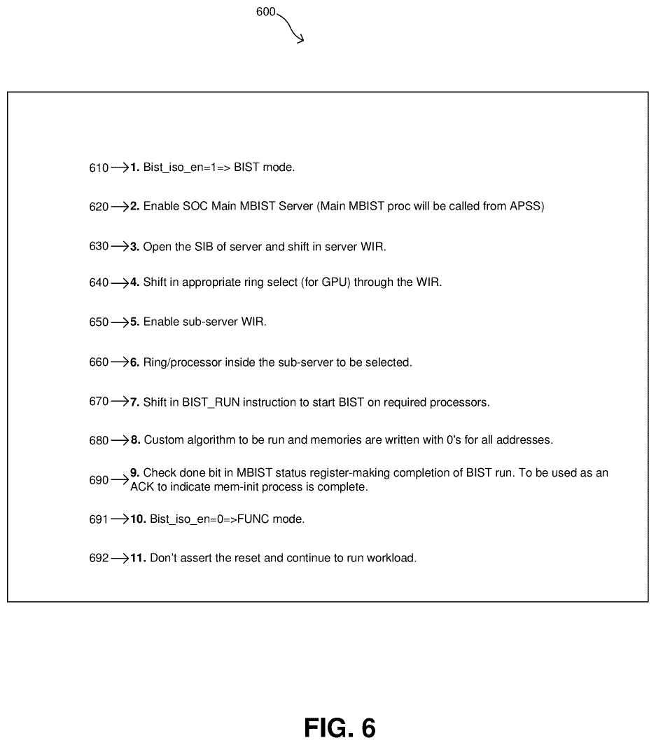

FIG. 6 illustrates an example hardware architecture and algorithm flow 600 for intrinsic memory initialization. In one example, a MBIST hardware in the automotive computing system may be used for memory initialization and a sequencer may be used to enter MBIST mode. In one example, lines 680 and 690 are entries in the algorithm flow to achieve intrinsic memory initialization.

In line 610, enter MBIST mode by enabling a BIST mode (e.g., setting Bist_iso_en to 1). In line 620, enable MBIST server (e.g., called from an application processor subsystem APSS). In line 630, open segment insertion bit (SIB) of MBIST server and shift in server write instruction register (WIR). In line 640, shift in appropriate ring select (for GPU) through the WIR. In line 650, enable sub-server WIR. In line 660, ring/processor inside sub-server is to be selected. In line 670, start BIST on required processors by shifting in BIST_RUN instruction. In line 680, run custom algorithm to write zeros for all memory addresses as memory initialization (i.e., a known pattern). In line 690, check if writing zeros is complete by checking done bit in MBIST status register (i.e., implement acknowledgment (ACK) process to indicate completion of memory initialization). In line 691, enter functional (FUNC) mode by disabling BIST mode (e.g., setting Bist_iso_en to 0) and start functional processing of workload. In line 692, continue running workload (i.e., without asserting reset).

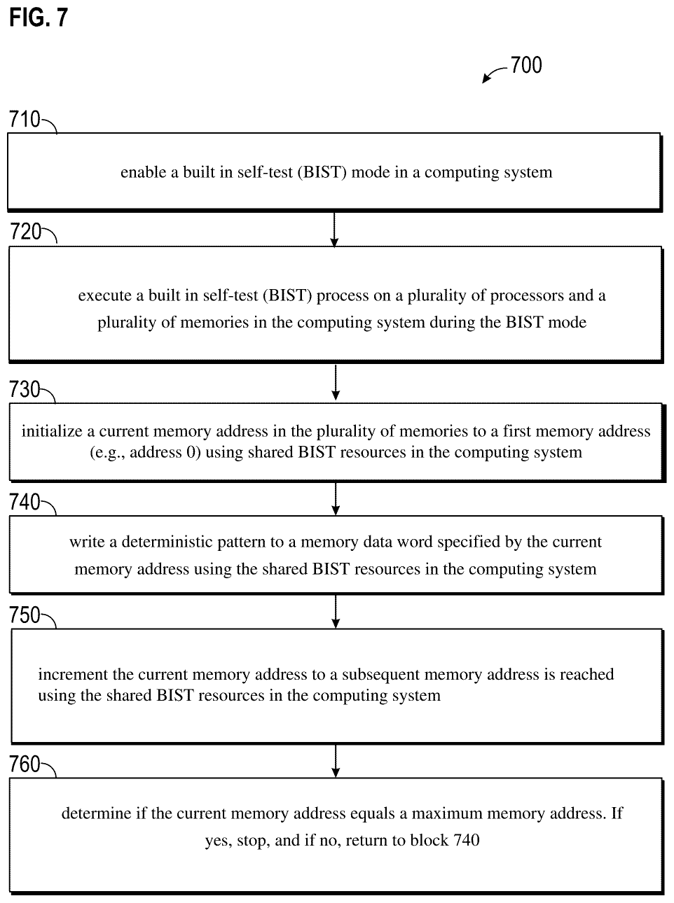

FIG. 7 illustrates an example flow diagram 700 for deterministic memory initialization. In block 710, enable a built-in self-test (BIST) mode in a computing system. In one example, a built-in self-test (BIST) mode is enabled in a computing system. In one example, the BIST mode includes a memory built-in self-test (MBIST) mode. In one example the BIST mode includes a logical built-in self-test (LBIST) mode.

In block 720, execute a built-in self-test (BIST) process on a plurality of processors and a plurality of memories in the computing system during the BIST mode. In one example, a built-in self-test (BIST) process is executed on a plurality of processors and a plurality of memories in the computing system during the BIST mode. In one example, the BIST process includes a MBIST process and a logical built-in self-test (LBIST) process.

In block 730, initialize a current memory address in the plurality of memories to a first memory address (e.g., address 0) using shared BIST resources in the computing system. In one example, a current memory address in the plurality of memories is initialized to a first memory address (e.g., address 0) using shared BIST resources in the computing system. In one example, the BIST hardware is MBIST hardware. In one example, the BIST hardware is a LBIST hardware. In one example, the current memory address specifies a memory location to enable access to a memory data word in main memory or in cache memory. In one example, the current memory address is hosted in a memory register or pointer register.

In block 740, write a deterministic pattern to a memory data word specified by the current memory address using the shared BIST resources in the computing system. In one example, a deterministic pattern is written to a memory data word specified by the current memory address using the shared BIST resources in the computing system. In one example, the deterministic pattern is all zeros. In one example, the deterministic pattern is a pseudorandom sequence generated by a finite state machine. In one example, a size of the deterministic pattern is congruent (i.e., having same quantity of bits) to a size of the memory data word.

In one example, the memory data word is part of a single port (SP) memory. In one example, the memory data word is part of a multiple port (MP) memory. In one example, the memory data word has an associated parity word. In one example, the associated parity word is an error correction code (ECC) word. In one example, the deterministic pattern is selected to initialize the memory data word to a known value. In one example, the shared BIST resources include MBIST hardware. In one example, the shared BIST resources include LBIST hardware. In one example, the MBIST hardware executes a sequence of diagnostic operations to validate proper memory functionality. In one example, the LBIST hardware executes a sequence of diagnostic operations to validate proper logic functionality.

In block 750, increment the current memory address to a subsequent memory address using the shared BIST resources in the computing system. In one example, the current memory address is incremented to a subsequent memory address using the shared BIST resources in the computing system. In one example, the subsequent memory address is equal to the current memory address plus a programmable positive offset value. In one example, the subsequent memory address is equal to the current memory address minus a programmable negative offset value. In one example, the shared BIST resources include MBIST hardware. In one example, the shared BIST resources include LBIST hardware.

In block 760, determine if the current memory address equals a maximum memory address. In one example, the current memory address is determined if it equals a maximum memory address. If yes, stop. If no, return to block 740. In one example, the maximum memory address is specified by a memory size in words or bytes.

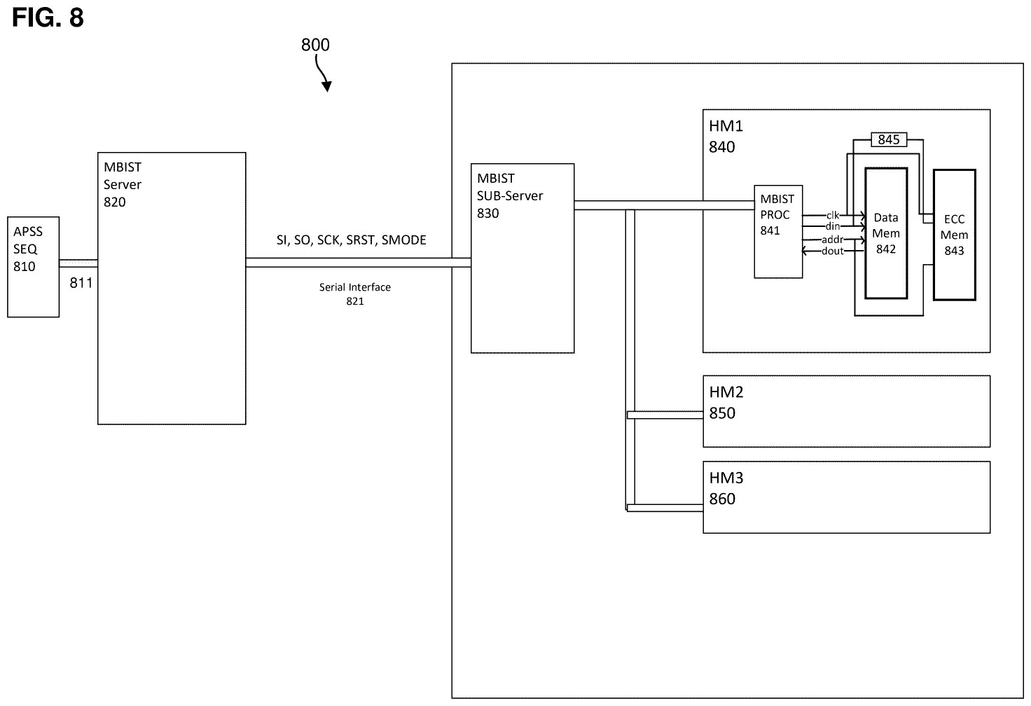

FIG. 8 illustrates an example intrinsic hardware implementation 800 for automotive computing system initialization. In one example, an application processor subsystem (APSS) sequencer 810 connects to a memory built-in self-test (MBIST) server 820 over an APSS software interface 811 to initialize a memory built-in self-test (MBIST) controller in MBIST mode. In one example, the MBIST server 820 connects to a memory built-in self-test (MBIST) subserver 830 over a serial interface 821 to transport a plurality of serial signals. For example, the plurality of serial signals includes serial data input (SI), serial data output (SO), serial clock (SCK), serial reset (SRST) and serial mode (SMODE). In one example, the serial interface may be utilized to select one hardware module (HM) out of a plurality of HMs.

In one example, the MBIST subserver 830 connects to a first HM 840, a second HM 850, and a third HM 860. In one example, the first HM 840 includes a memory built-in self-test (MBIST) processor 841 connected to a data memory 842 and an error correction coding (ECC) memory 843 using a plurality of memory signals 844 to initialize the data memory 842 and the ECC memory 843. In one example, the plurality of memory signals 844 include a clock (clk), a data input (din), a data output (dout) and an address (addr). In one example, the first HM 840 also includes an error correction coding (ECC) encoder 845. In one example, the ECC encoder 845 computes parity bits based on data bits stored in the data memory 842. In one example, the parity bits are stored in the ECC memory 843. In one example, the second HM 850 and the third HM 860 are configured similarly to the first HM 840.

In one aspect, one or more of the steps for providing deterministic memory initialization in FIG. 7 may be executed by one or more processors which may include hardware, software, firmware, etc. The one or more processors, for example, may be used to execute software or firmware needed to perform the steps in the flow diagram of FIG. 7. Software shall be construed broadly to mean instructions, instruction sets, code, code segments, program code, programs, subprograms, software modules, applications, software applications, software packages, routines, subroutines, objects, executables, threads of execution, procedures, functions, etc., whether referred to as software, firmware, middleware, microcode, hardware description language, or otherwise.

The software may reside on a computer-readable medium. The computer-readable medium may be a non-transitory computer-readable medium. A non-transitory computer-readable medium includes, by way of example, a magnetic storage device (e.g., hard disk, floppy disk, magnetic strip), an optical disk (e.g., a compact disc (CD) or a digital versatile disc (DVD)), a smart card, a flash memory device (e.g., a card, a stick, or a key drive), a random access memory (RAM), a read only memory (ROM), a programmable ROM (PROM), an erasable PROM (EPROM), an electrically erasable PROM (EEPROM), a register, a removable disk, and any other suitable medium for storing software and/or instructions that may be accessed and read by a computer. The computer-readable medium may also include, by way of example, a carrier wave, a transmission line, and any other suitable medium for transmitting software and/or instructions that may be accessed and read by a computer. The computer-readable medium may reside in a processing system, external to the processing system, or distributed across multiple entities including the processing system. The computer-readable medium may be embodied in a computer program product. By way of example, a computer program product may include a computer-readable medium in packaging materials. The computer-readable medium may include software or firmware. Those skilled in the art will recognize how best to implement the described functionality presented throughout this disclosure depending on the particular application and the overall design constraints imposed on the overall system.

Any circuitry included in the processor(s) is merely provided as an example, and other means for carrying out the described functions may be included within various aspects of the present disclosure, including but not limited to the instructions stored in the computer-readable medium, or any other suitable apparatus or means described herein, and utilizing, for example, the processes and/or algorithms described herein in relation to the example flow diagram.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another-even if they do not directly physically touch each other. The terms “circuit” and “circuitry” are used broadly, and intended to include both hardware implementations of electrical devices and conductors that, when connected and configured, enable the performance of the functions described in the present disclosure, without limitation as to the type of electronic circuits, as well as software implementations of information and instructions that, when executed by a processor, enable the performance of the functions described in the present disclosure.

One or more of the components, steps, features and/or functions illustrated in the figures may be rearranged and/or combined into a single component, step, feature or function or embodied in several components, steps, or functions. Additional elements, components, steps, and/or functions may also be added without departing from novel features disclosed herein. The apparatus, devices, and/or components illustrated in the figures may be configured to perform one or more of the methods, features, or steps described herein. The novel algorithms described herein may also be efficiently implemented in software and/or embedded in hardware.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “step for.”

One skilled in the art would understand that various features of different embodiments may be combined or modified and still be within the spirit and scope of the present disclosure.

What is claimed is:

1. An apparatus comprising:
a memory configured to store a memory data word; and
a memory built-in self-test (MBIST) module coupled to the memory, the MBIST module configured to implement diagnostic check of the memory and to initialize the memory with a deterministic pattern.

2. The apparatus of claim 1, further comprising:
a processor coupled to the memory; and
a logical built-in self-test (LBIST) module coupled to the processor, the LBIST module configured to validate logic functionality of the processor.

3. The apparatus of claim 2, wherein the MBIST module is further configured to write the deterministic pattern to the memory data word specified by a current memory address using a plurality of shared built-in self-test (BIST) resources.

4. The apparatus of claim 3, wherein the deterministic pattern is a pseudorandom sequence generated by a finite state machine.

5. The apparatus of claim 3, wherein the memory data word includes an associated parity word.

6. The apparatus of claim 4, wherein the MBIST module is further configured to increment the current memory address to a subsequent memory address using the plurality of shared BIST resources.

7. An apparatus for implementing deterministic memory initialization, the apparatus comprising:
means for initializing a current memory address in a plurality of memories to a memory address using a plurality of shared built-in self-test (BIST) resources in a computing system;
means for writing a deterministic pattern to a memory data word specified by the current memory address using the plurality of shared BIST resources;
means for incrementing the current memory address to a subsequent memory address using the plurality of shared BIST resources; and
means for determining if the current memory address equals a maximum memory address.

8. The apparatus of claim 7, further comprising
means for executing a built-in self-test (BIST) process on a plurality of processors and a plurality of memories in the computing system during built-in self-test (BIST) mode; and
means for enabling the BIST mode in the computing system.

9. A method comprising:
initializing a first current memory address in a plurality of memories to a first memory address using a plurality of shared built-in self-test (BIST) resources;
writing a first deterministic pattern to a first memory data word specified by the first current memory address using the plurality of shared BIST resources; and
incrementing the first current memory address to a first subsequent memory address using the plurality of shared BIST resources.

10. The method of claim 9, wherein the first deterministic pattern is all zeros.

11. The method of claim 9, wherein the first deterministic pattern is a pseudorandom sequence generated by a finite state machine.

12. The method of claim 9, wherein a size of the first deterministic pattern is congruent to a size of the first memory data word.

13. The method of claim 12 wherein the first memory data word includes an associated parity word.

14. The method of claim 9, further comprising determining if the first current memory address equals a maximum memory address.

15. The method of claim 14, further comprising:
writing a second deterministic pattern to a second memory data word specified by the first subsequent memory address using the plurality of shared BIST resources;
incrementing the first subsequent memory address to a second subsequent address using the plurality of shared BIST resources; and
determining if the second subsequent memory address equals the maximum memory address.

16. The method of claim 14, further comprising executing a built-in self-test (BIST) process on a plurality of processors and a plurality of memories in a computing system during built-in self-test (BIST) mode.

17. The method of claim 16, further comprising selecting the first deterministic pattern to initialize the first memory data word to a known value.

18. The method of claim 17, wherein the first subsequent memory address is equal to the first current memory address plus a programmable positive offset value.

19. The method of claim 17, wherein the first subsequent memory address is equal to the first current memory address minus a programmable negative offset value.

20. The method of claim 16, further comprising enabling the BIST mode in the computing system, wherein the first current memory address is initialized in the plurality of memories to the first memory address using the plurality of shared BIST resources in the computing system.
